(19) United States
(12) Patent Application Publication
(10) Pub. No.: US 2023/0170353 A1
(43) Pub. Date: Jun. 1, 2023

(54) DISPLAY APPARATUS, METHOD OF MANUFACTURING DISPLAY APPARATUS, AND ELECTRONIC APPARATUS

(71) Applicant: Sony Semiconductor Solutions Corporation, Kanagawa (JP)

(72) Inventor: Kenichi Aoyagi, Kanagawa (JP)

(21) Appl. No.: 17/921,567

(22) PCT Filed: Jun. 9, 2021
(86) PCT No.: PCT/JP2021/021925

§ 371 Date: Oct. 26, 2022

(30) Foreign Application Priority Data
Jun. 18, 2020 (JP) 2020-104965

(51) Int. Cl. H01L 27/12; H10K 59/131; H10K 59/12; G09G 3/3233

(52) U.S. Cl. CPC H01L 27/1233; H10K 59/131; H10K 59/1201; G09G 3/3233; H10K 59/1213

(57) ABSTRACT

There is provided a display apparatus including: a first semiconductor substrate (100) provided with a drive circuit unit (40) including a pixel transistor group including a plurality of pixel transistors (400) that drives a light emitting unit (20); and a second semiconductor substrate (200) provided with the light emitting unit and a peripheral circuit unit (30) including a plurality of peripheral circuit transistors (300) that supplies a signal voltage to the drive circuit unit, the second semiconductor substrate being stacked on the first semiconductor substrate and bonded to the first semiconductor substrate, wherein a film thickness of a gate oxide film (404) of each of the plurality of pixel transistors is larger than a film thickness of a gate oxide film (304) of each of the plurality of peripheral circuit transistors.

### FIELD

The present disclosure relates to a display apparatus, a method of manufacturing a display apparatus, and an electronic apparatus.

### BACKGROUND

In recent years, as a display apparatus replacing a liquid crystal display, an organic electroluminescence display (referred to as an organic EL display) using an organic electroluminescence element (hereinafter referred to as an organic EL element) has been developed (for example, Patent Literature 1 cited below).

### CITATION LIST

### Patent Literature

Patent Literature 1: JP 2014-98779 A

### SUMMARY

### Technical Problem

Recently, there is a strong demand for higher definition and higher resolution of the above-described organic EL display. In order to meet such a demand, the number of pixels increases and the number of operations of data processing also increases in the above-described display apparatus, which involves an increase of as area of a peripheral circuit unit that performs data processing. Then, in order to mitigate an increase of an area of the peripheral circuit unit, a peripheral circuit transistor provided in the peripheral circuit unit is required to be a small-area transistor using a microfabrication process. Meanwhile, a relatively high voltage is applied to drive an organic EL element of the organic EL display. For this reason, a pixel transistor forming a drive circuit that drives each organic EL element is required to have a high breakdown voltage. That is, the pixel transistor is required to have characteristics and configurations different from those of the above-described peripheral circuit transistor manufactured by a microfabrication process.

Therefore, it is difficult to efficiently manufacture the minute peripheral circuit transistor of the peripheral circuit unit and the pixel transistor of the drive circuit unit in the organic EL display due to their different characteristics and configurations.

In view of the above-described circumstances, the present disclosure proposes a display apparatus, a method of manufacturing a display apparatus, and an electronic apparatus that can mitigate an increase of a mounting area and allow efficient manufacture while meeting a demand for higher definition and higher resolution.

### Solution to Problem

According to the present disclosure, a display apparatus is provided. The display apparatus includes: a first semiconductor substrate provided with a drive circuit unit including a pixel transistor group including a plurality of pixel transistors that drives a light emitting unit; and a second semiconductor substrate provided with the light emitting unit and a peripheral circuit unit including a plurality of peripheral circuit, transistors that supplies a signal voltage to the drive circuit unit, the second semiconductor substrate being stacked on the first semiconductor substrate and bonded to the first semiconductor substrate. In the display apparatus, a film thickness of a gate oxide film of each of the plurality of pixel transistors is larger than a film thickness of a gate oxide film of each of the plurality of peripheral circuit transistors.

Also, according to the present disclosure, a method of manufacturing a display apparatus is provided. The method includes: forming a first semiconductor substrate provided with a drive circuit unit including a pixel transistor group including a plurality of pixel transistors that drives a light emitting unit; forming a second semiconductor substrate provided with the light emitting unit and a peripheral circuit unit including a plurality of peripheral circuit transistors that supplies a signal voltage to the drive circuit unit; and stacking the second semiconductor substrate on the first semiconductor substrate to bond the substrates. In forming the first semiconductor substrate, the plurality of pixel transistors are formed such that a film thickness of a gate oxide film of each of the plurality of pixel transistors is larger than a film thickness of a gate oxide film of each of the plurality of peripheral circuit transistors.

Moreover, according to the present disclosure, an electronic apparatus is provided. One or a plurality of display apparatuses is mounted in the electronic apparatus. The display apparatuses each include: a first semiconductor substrate provided with a drive circuit unit including a pixel transistor group including a plurality of pixel transistors that drives a light emitting unit; and a second semiconductor substrate provided with the light emitting unit and a peripheral circuit unit including a plurality of peripheral circuit transistors that supplies a signal voltage to the drive circuit unit, the second semiconductor substrate being stacked on the first semiconductor substrate and bonded to the first semiconductor substrate. In the display apparatus, a film thickness of a gate oxide film of each of the plurality of pixel transistors is larger than a film thickness of a gate oxide film of each of the plurality of peripheral circuit transistors.

### BRIEF DESCRIPTION OF DRAWINGS

FIG. 1 is a sectional view diagrammatically illustrating an example of a plan-view structure of a display apparatus 10 according to an embodiment of the present disclosure.

FIG. 2 is an equivalent circuit diagram of an example of a drive circuit unit 40 of the display apparatus 10 according to the embodiment of the present disclosure.

FIG. 3 is a sectional view diagrammatically illustrating an example of a sectional structure of the display apparatus 10 according to a first embodiment of the present disclosure.

FIG. 4 is a sectional view diagrammatically illustrating another example of a sectional structure of a display apparatus 10a according to the first embodiment of the present disclosure.

FIG. 5A is an explanatory view (part 1) for explaining a method of manufacturing the display apparatus 10a according to the first embodiment of the present disclosure.

FIG. 5B is an explanatory view (part 2) for explaining the method of manufacturing the display apparatus 10a according to the first embodiment of the present disclosure.

FIG. 5C is an explanatory view (part 3) for explaining the method of manufacturing the display apparatus 10a according to the first embodiment of the present disclosure.

FIG. 5D is an explanatory view (part 4) for explaining the method of manufacturing the display apparatus 10a according to the first embodiment of the present disclosure.

FIG. 6 is a sectional view diagrammatically illustrating an example of a sectional structure of a display apparatus 10b according to a second embodiment of the present disclosure.

FIG. 7A is an explanatory view (part 1) for explaining a method of manufacturing the display apparatus 10b according to the second embodiment of the present disclosure.

FIG. 7B is an explanatory view (part 2) for explaining the method of manufacturing the display apparatus 10b according to the second embodiment of the present disclosure.

FIG. 7C is an explanatory view (part 3) for explaining the method of manufacturing the display apparatus 10b according to the second embodiment of the present disclosure.

FIG. 7D is an explanatory view (part 4) for explaining the method of manufacturing the display apparatus 10b according to the second embodiment of the present disclosure.

FIG. 7E is an explanatory view (part 5) for explaining the method of manufacturing the display apparatus 10b according to the second embodiment of the present disclosure.

FIG. 8 is a sectional view diagrammatically illustrating an example of a sectional structure of a display apparatus 10c according to a third embodiment of the present disclosure.

FIG. 9 is an external view illustrating an example of an electronic apparatus to which the display apparatus 10 according to the embodiment of the present disclosure can be applied.

FIG. 10 is an external view illustrating another example of an electronic apparatus to which the display apparatus 10 according to the embodiment of the present disclosure can be applied.

FIG. 11 is an external view illustrating another different example of an electronic apparatus to which the display apparatus 10 according to the embodiment of the present disclosure can be applied.

FIG. 12 is an external view illustrating another different example of an electronic apparatus to which the display apparatus 10 according to the embodiment of the present disclosure can be applied.

### DESCRIPTION OF EMBODIMENTS

Below, preferred embodiments of the present disclosure will be described in detail with reference to the accompanying drawings. Note that, in the present specification and the drawings, components having substantially the same functional configuration are denoted by the same reference signs, and duplicated description is omitted.

Further, in the present specification and the drawings, similar components of different embodiments are distinguished by different alphabets at the ends of the same reference signs, in some portions. However, the similar components are denoted by only the same reference signs unless they need to be distinguished from each other.

Further, the drawings referred to in the following description are drawings for promoting the description of the embodiments of the present disclosure and the understanding thereof, and shapes, dimensions, ratios, and the like illustrated in the drawings are different from actual ones for the sake of clarity in some cases. Moreover, a display apparatus and components included in the display apparatus illustrated in the drawings are susceptible to design change in consideration of the following description and known techniques, as appropriate. Moreover, in the following description, the longitudinal direction of a layered structure of the display apparatus corresponds to a relative direction in a case where the display apparatus is placed such that light emitted from the display apparatus is directed from bottom to top, unless otherwise specified.

In the following description, the terms “substantially the same” mean not only a case in which given numbers are mathematically the same or equal, but also a case in which there is an allowable difference (error) in the operation of a display apparatus according to an embodiment of the present disclosure.

Further, in the following description about circuits (electrical connection), the terms “electrically connected” mean that a plurality of elements is connected so as to allow conduction of electricity (signals) therebetween, unless otherwise specified. In addition, the terms “electrically connected” in the following description include not only a case in which a plurality of elements is directly and electrically connected, but also a case in which a plurality of elements is indirectly and electrically connected via other elements.

The description will be given in the following order.
1. Background that has led the present inventors to make embodiments of the present disclosure
1.1 Plan-view structure
1.2 Equivalent circuit of drive circuit unit
1.3 Background
2. First embodiment
2.1 Sectional structure
2.2 Modifications
2.3 Manufacturing method
3. Second embodiment
3.1 Sectional structure
3.2 Manufacturing method
4. Third embodiment
5. Conclusion
6. Application examples
7. Supplement

### 1. Background that has Led the Present Inventors to Make Embodiments of the Present Disclosure

First, prior to describing the embodiments of the present disclosure in detail, the background that has led the present inventors to make the embodiments of the present disclosure will be described.

<1.1 Plan-View Structure>

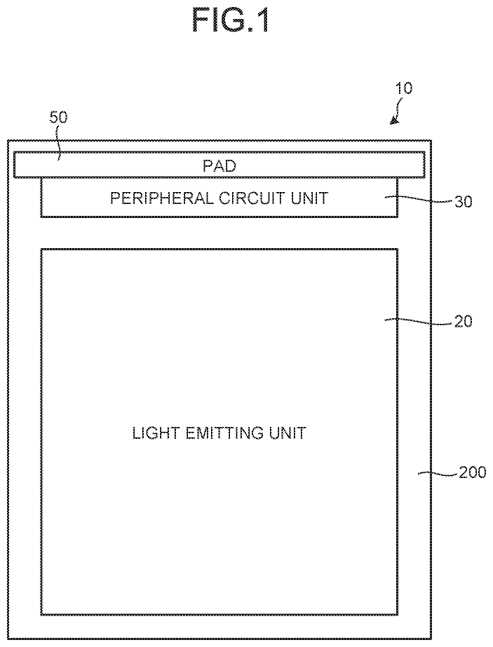

An example of a plan-view structure of a display apparatus 10 according to the embodiment of the present disclosure will be described with reference to FIG. 1. FIG. 1 is a sectional view diagrammatically illustrating an example of a plan-view structure of the display apparatus 10 according to the embodiment of the present disclosure. In the following description, an organic EL display will be described as an example of the display apparatus 10 of the present embodiment.

The display apparatus 10 according to the embodiment of the present disclosure is formed by a process in which a semiconductor substrate 100 and a semiconductor substrate 200 are stacked and the semiconductor substrates 100 and 200 are bonded to each other, details of which will be given later. Note that the semiconductor substrates 100 and 200 may be, for example, monocrystalline silicon (Si) substrates or other semiconductor substrates such as silicon carbide (SiC) substrates. Then, FIG. 1 illustrates a plan view of the display apparatus 10 as viewed from above (from above a light emitting unit 20), in other words, a plan view of the semiconductor substrate 200 positioned on the upper side in the above-described stack, as viewed from above.

Specifically, as illustrated In FIG. 1, the semiconductor substrate 200 is mainly provided with a light emitting unit 20, a peripheral circuit unit 30, and a pad 50. Below, details of each block provided in the semiconductor substrate 200 of the display apparatus 10 according to the present embodiment will be given.

(Light Emitting Unit 20)

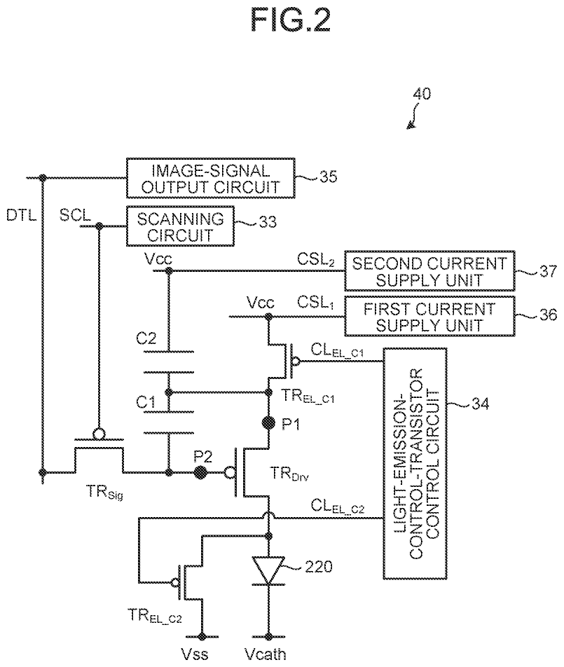

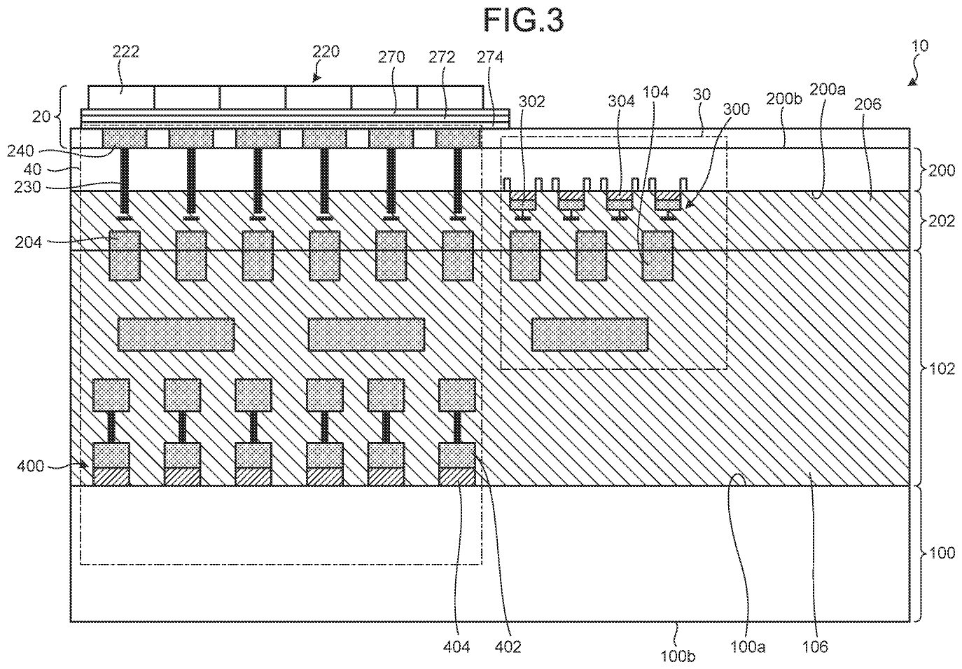

The light emitting unit 20 includes a plurality of light emitting elements 220 (see FIG. 3) arranged in a matrix along a horizontal direction and a vertical direction (a row direction and a column direction). The light emitting element 220 can be, for example, an organic electronic luminescent (EL) element (OLED) having light emission luminance that varies depending on the magnitude of a supplied current. More specifically, each light emitting element 220 has a known configuration or structure including an anode electrode 240, an organic material layer 274, a cathode electrode 272, an insulating film 270, color filters 222 of different colors (blue, red, green), and the like (see FIG. 3). Further, the organic material layer has a structure in which a hole transport layer (not illustrated), a light emitting layer (not illustrated), and an electron transport layer (not illustrated) are stacked, for example. In the following description, it is assumed that one light emitting element 220 is provided for each color filter 222. Further, a drive circuit block (pixel transistor group) that drives the light emitting elements 220 may be provided for each light emitting elements 220. Note that one or a plurality of drive circuit blocks forms a drive circuit unit 40 (see FIGS. 2 and 3) described later.

In the present embodiment, the display apparatus 10 may be configured to perform monochrome display or color display. Further, in the case of a color display configuration, the light emitting element 220 may have a configuration including the anode electrode 240, the organic material layer 274, the cathode electrode 272, the insulating film 270, and the like, without the color filter 222.

(Peripheral Circuit Unit 30)

As illustrated in FIG. 1, the peripheral circuit unit 30 is a circuit unit that is positioned around the light emitting unit 20 and supplies a signal voltage or a power supply voltage to the drive circuit unit 40 described above. More specifically, the peripheral circuit unit 30 can include a horizontal scanning circuit (not illustrated), a vertical scanning circuit (not illustrated), a gamma voltage generation circuit (not illustrated), a timing controller (not illustrated), a digital/analog (D/A) converter (not illustrated), an amplifier (not illustrated), an interface (not illustrated), a memory (not illustrated), and the like, for example. Further, the peripheral circuit unit 30 may include a test circuit (not illustrated). Note that, in the following description, the horizontal scanning circuit corresponds to a scanning circuit 33 and a light-emission-control-transistor control circuit 34, and the vertical scanning circuit corresponds to an image-signal output circuit 35 (see FIG. 2)

(Pad 50)

The pad 50 is a pad for electrically connecting the cathode electrode 272 (see FIG. 3) of the light emitting element 220 of the light emitting unit 20 to a power supply circuit and for electrically connecting various transistors to the power supply circuit to apply a voltage to the various transistors. The pad 50 is formed of, for example, a conductive material such as a metal film.

Note that the example of the plan-view structure of the display apparatus 10 according to the present embodiment is not limited to the example illustrated in FIG. 1, and may include another circuit unit and the like, for example.

<1.2 Equivalent Circuit of Drive Circuit Unit>

Next, an equivalent circuit of the drive circuit unit 40 of the display apparatus 10 according to the embodiment of the present disclosure will be described with reference to FIG. 2. FIG. 2 is an equivalent circuit diagram of an example of the drive circuit unit 40 of the display apparatus 10 according to the embodiment of the present disclosure. Specifically, the equivalent circuit illustrated in FIG. 2 includes a drive circuit block (pixel transistor group) provided for each pixel (for each light emitting element 220). In the following description, a 4Tr-2C-type circuit configuration having four transistors and two capacitors will be described as an example of the drive circuit block of the drive circuit unit 40, but the present embodiment is not limited thereto. In the present embodiment, for example, a 3Tr-2C-type circuit configuration having three transistors and two capacitors, a 4Tr-1C-type circuit configuration having four transistors and one capacitor, a 3Tr-1C-type circuit configuration having three transistors and one capacitor, and the like can be applied.

The drive circuit unit 40 is a circuit unit that drives the light emitting element 220 of the light emitting unit 20, and is formed of one or a plurality of drive circuit blocks illustrated in FIG. 2 as described above (see FIG. 3).

As illustrated in FIG. 2, the drive circuit unit 40 can include four transistors (pixel transistors) (a drive transistor TR_{Drv}, an image-signal writing transistor TR_{Sig}, a first light-emission control transistor TR_{EL_C1}, and a second light-emission control transistor TR_{EL_C2}), two capacitors (a first capacitor C1, a second capacitor C2), and various signal lines (a scanning line SCL, a data line DTL, a first current supply line CSL₁, a second current supply line CSL₂, a first light-emission control line CL_{EL_C1}, and a second light-emission control line CL_{EL_C2}). The drive circuit unit 40 includes a transistor group (pixel transistor group) that is provided to correspond to each of the plurality of light emitting elements 220 forming the light emitting unit 20 and includes the above-described four transistors and two capacitors.

The drive transistor TR_{Drv} is a transistor that controls a current flowing through the light emitting unit 20 to drive the light emitting element 220. The drive transistor TR_{Drv} includes one of a source and a drain connected to the anode of the light emitting unit 20, the other of the source and the drain connected to one of a source and a drain of the first light -emission control transistor TR_{EL_C1}, and a gate connected to one of a source and a drain of the image-signal writing transistor TR_{sig} and to one of electrodes of the first capacitor C1.

The image-signal writing transistor TR_{Sig} is a transistor that performs switching on a signal voltage (row selection signal) and selects a row in accordance with the signal voltage. The image-signal writing transistor TR_{Sig} has the other of the source and the drain connected to the image-signal output circuit 35 via the data line DTL and a gate connected to the scanning circuit 33 via the scanning line SCL.

The first light-emission control transistor TR_{EL_C1} is a transistor that performs switching on a power supply voltage (column selection signal) and selects a column in accordance with the power supply voltage. The first light-emission control transistor TR_{EL_C1} has the other of the source and the drain connected to a first current supply unit 36 via the first current supply line CSL₁ and a gate connected to the light-emission-control-transistor control circuit 34 via the first light-emission control line CL_{EL_C1}. The other of the source and the drain of the first light-emission control transistor TR_{EL_C1} is applied with a drive voltage V_{cc} by the first current supply unit 36.

The second light-emission control transistor TR_{EL_C2} is a transistor that resets a voltage (anode voltage) applied to the light emitting unit 20. The second light-emission control transistor TR_{EL_C2} has one of a source and a drain connected to the anode of the light emitting unit 20, the other of the source and the drain connected to a reset volt age line V_{SS}, and a gate connected to the light-emission-control-transistor control circuit 34 via the second light-emission control line CL_{EL_C2}.

The first capacitor C1 and the second capacitor C2 are connected in series with each other. One of the electrodes of the first capacitor C1 is connected to the gate of the drive transistor TR_{Drv} and to the one of the source and the drain of the image-signal writing transistor TR_{Sig}. The other of the electrodes of the first capacitor C1 and one of electrodes of the second capacitor C2 are connected to the other of the source and the drain of the drive transistor TR_{Drv} and to the one of the source and the drain of the first light-emission control transistor TR_{EL_C1}. The other of the electrodes of the second capacitor C2 is connected to a second current supply unit 37 via the second current supply line CSL₂. The other of the electrodes of the second capacitor C2 is applied with the drive voltage V_{cc} by the second current supply unit 37.

As described above, each light emitting element 220 has a known configuration or structure including the anode electrode 240, the organic material layer 274, the cathode electrode 272, the insulating film 270, the color filters 222, and the like (see FIG. 3). Then, the above-described anode electrode 240 is connected to the one of the source and the drain of the drive transistor TR_{Drv} and to the one of the source and the drain of the second light-emission control transistor TR_{EL_C2}. Further, the above-described cathode electrode 272 is connected to a power supply line V_{cath}.

Further, in the present embodiment, the drive transistor TR_{Drv}, the image-signal writing transistor TR_{Sig}, the first light-emission control transistor TR_{EL_C1}, and the second light-emission control transistor are each formed of, for example, a p-type channel metal oxide semiconductor field effect transistor (MOSFET), and are formed in an n-type well formed in a p-type silicon semiconductor substrate.

Note that the example of the circuit configuration of the drive circuit unit 40 according to the present embodiment is not limited to the example illustrated in FIG. 2, as described above.

<1.3 Background>

As described above, as the display apparatus 10, an organic electroluminescence display using an organic EL element, for example, has been developed, but the number of pixels of the light emitting unit 20 (the number of light emitting elements 220) has increased in response to a demand for higher definition and higher resolution (for example, 4K, 8K). As the number of pixels increases, the number of wires in the peripheral circuit unit 30 also increases, and routing of the wires becomes complicated due to the increasing number of wires, resulting in an increase of the area of the peripheral circuit unit 30.

Further, the peripheral circuit unit 30 is required to perform high-speed processing in the peripheral circuit unit 30 because the number of operations of data processing increases due to an increase of the number of pixels. Therefore, the peripheral circuit transistors 300 (see FIG. 3) included in the peripheral circuit unit 30 are each required to be a small-area transistor that is formed using a microfabrication process and can prevent a delay from occurring while mitigating an increase of the area of the peripheral circuit unit 30 despite the number of peripheral circuit transistors increasing as the number of operations of data processing increases.

Meanwhile, pixel transistors 400 (see FIG. 3) that are included in the drive circuit unit 40 and drive the light emitting elements 220 including organic EL elements are each required to have a high breakdown voltage because of a high drive voltage applied to the light emitting elements 220. Therefore, the pixel transistor 400 should have an increased area and include a gate oxide film 404 (see FIG. 3) with an increased thickness, for example, in order to increase its breakdown voltage. That is, the pixel transistor 400 is required to have characteristics and configurations different from those of the above-described peripheral circuit transistor 300 manufactured by a microfabrication process.

Thus, in manufacture of the above-described display apparatus 10, it is difficult to efficiently and suitably manufacture the peripheral circuit transistor 300 of the peripheral circuit unit 30 and the pixel transistor 400 of the drive circuit unit 40 in the same process, due to their different characteristics and configurations.

In view of the above-described circumstances, the present inventors have been led to devise the display apparatus 10 according to the embodiment of the present disclosure that can mitigate an increase of a mounting area and allow efficient manufacture while meeting a demand for higher definition and higher resolution. Below, details of the embodiments of the present disclosure will be sequentially given.

### 2. First Embodiment

<2.1 Sectional Structure>

First, a sectional structure of the display apparatus 10 according to a first embodiment of the present disclosure will be described with reference to FIG. 3. FIG. 3 is a sectional view diagrammatically illustrating an example of a sectional structure of the display apparatus 10 according to the present embodiment. In FIG. 3, gate oxide films 304 and 404 are illustrated such that they are thicker than layers other than the gate oxide films 304 and 404 for the purpose of emphasizing that their film thicknesses differ depending on in which transistor they are included, in the present embodiment.

As illustrated in FIG. 3, the display apparatus 10 of the present embodiment is formed of a layered structure of the semiconductor substrate (first semiconductor substrate) 100 and the semiconductor substrate (second semiconductor substrate) 200. Specifically, the semiconductor substrate 200 is stacked on the semiconductor substrate 100 and bonded to the semiconductor substrate 100. Below, details of the semiconductor substrates 100 and 200 will be sequentially given.

(Semiconductor Substrate 100)

The semiconductor substrate 100 includes a part of the drive circuit unit 40 including a pixel transistor group including the plurality of pixel transistors 400 that drive the light emitting unit 20. Specifically, the semiconductor substrate 100 includes the plurality of pixel transistors 400 provided on a side closer to a surface 100a of the semiconductor substrate 100 facing the semiconductor substrate 200.

Each pixel transistor 400 includes the gate oxide film 404 that is provided on the surface 100a of the semiconductor substrate 100 and is made of a silicon oxide film or the like, and a gate electrode 402 that is provided on the gate oxide film 404 and is made of a metal film, a polysilicon film, or the like. Note that, in the present embodiment, the pixel transistor 400 includes at least one of the four transistors (TR_{Drv}, TR_{Sig}, TR_{EL_C1}, TR_{EL_C2}) that have been described with reference to FIG. 2. That is, in the present embodiment, at least one of the four transistors is provided on the semiconductor substrate 100. Further, in the present embodiment, among the four transistors, a transistor that is not provided on the semiconductor substrate 100 may be provided on the semiconductor substrate 200. Further, the gate oxide film 404 of the pixel transistor 400 is thicker than the gate oxide film 304 of the peripheral circuit transistor 300 of the peripheral circuit unit 30 described later. This allows the pixel transistor 400 to suitably operate despite a high drive voltage applied to the light emitting element 220.

Moreover, two capacitors (C1, C2) included in the drive circuit unit 40 described with reference to FIG. 2 can also be provided on the semiconductor substrate 100. For example, although not illustrated in FIG. 3, each of the capacitors C1 and C2 (see FIG. 2) can include a pair of electrodes (not illustrated) provided on the semiconductor substrate 100 and a dielectric film (not illustrated) sandwiched between the pair of electrodes.

Furthermore, the semiconductor substrate 100 includes a wiring layer 102 on the surface 100a on a side closer to the semiconductor substrate 200. Specifically, the wiring layer 102 included in the semiconductor substrate 100 includes an insulating film 106 and a plurality of wires 104 provided in the insulating film 106. For example, the wires 104 can electrically connect the pixel transistors 400 to the light emitting elements 220 of the light emitting unit 20 or electrically connect the pixel transistors 400 to another circuit block (the peripheral circuit unit 30, for example). The wires 104 can be formed of, for example, a metal material or a metal compound material containing a metal such as gold, silver, copper, platinum, aluminum, tungsten, zinc, or tin. Further, the insulating film 106 can be formed of an insulating film such as a silicon oxide film or a silicon nitride film. Moreover, the wiring layer 102 faces the semiconductor substrate 200 and is bonded to a wiring layer 202 provided on the semiconductor substrate 200, whereby the semiconductor substrate 100 and the semiconductor substrate 200 can be bonded (details of the bonding will be given later).

(Semiconductor Substrate 200)

In the semiconductor substrate 200, the light emitting unit 20 including the plurality of light emitting elements 220 is provided on a surface (second surface) 200b opposite to a surface (first surface) 200a facing the semiconductor substrate 100 with an insulating film 270 formed of a silicon oxide film, a silicon nitride film, or the like, interposed therebetween. Further, the light emitting unit 20 is positioned immediately above the drive circuit unit 40 along a stacking direction (longitudinal direction in FIG. 3) of the display apparatus 10.

Further, the semiconductor substrate 200 includes the peripheral circuit unit 30 around the light emitting unit 20. Specifically, the peripheral circuit unit 30 includes the plurality of peripheral circuit transistors 300 provided on a side closer to the surface (first surface) 200a of the semiconductor substrate 200 facing the semiconductor substrate 100. Further, the peripheral circuit transistor 300 includes the gate oxide film 304 that is provided on the surface 200a of the semiconductor substrate 200 and is made of a silicon oxide film or the like, and a gate electrode 302 that is provided on the gate oxide film 304 and is made of a metal film, a polysilicon film, or the like. Then, in the present embodiment, as described above, the gate oxide film 304 of the peripheral circuit transistor 300 may have a breakdown voltage lower than that of the pixel transistor 400, and thus, is thinner than the gate oxide film 404 of the pixel transistor 400 of the drive circuit unit 40 described above. Further, in the present embodiment, the peripheral circuit transistor 300 can be a transistor that is more minute, in other words, is smaller in area than the above-described pixel transistor 400. As a result of this, despite an increase of the number of the peripheral circuit transistors 300 for higher definition and higher resolution of the display apparatus 10, it is possible to prevent a delay from occurring while mitigating an increase of the area of the peripheral circuit unit 30.

Further, the semiconductor substrate 200 includes the wiring layer 202 on the surface 200a. Specifically, the wiring layer 202 included in the semiconductor substrate 200 includes an insulating film 206 and the plurality of wires 204 provided in the insulating film 206. For example, the wires 204 can electrically connect the light emitting elements 220 of the light emitting unit 20 to the pixel transistors 400 provided on the semiconductor substrate 100. The wires 204 can be formed of, for example, a metal material or a metal compound material containing a metal such as gold, silver, copper, platinum, aluminum, tungsten, zinc, or tin. Further, the insulating film 206 can be formed of an insulating film such as a silicon oxide film or a silicon nitride film. Moreover, the wiring layer 202 faces the semiconductor substrate 100 and is bonded to the wiring layer 102 provided on the semiconductor substrate 100, whereby the semiconductor substrate 100 and the semiconductor substrate 200 can be bonded (details of the bonding will be given later).

Furthermore, the semiconductor substrate 200 includes a part of the drive circuit unit 40. Specifically, the semiconductor substrate 200 includes a via 230 that passes through the semiconductor substrate 200 to electrically connect the light emitting element 220 of the light emitting unit 20 to the pixel transistor 400 provided on the semiconductor substrate 100. The via 230 is formed of, for example, a metal film containing copper, tungsten, aluminum, tantalum, or the like. Note that the via 230 may be provided with an insulating film (not illustrated) that is made of a silicon oxide film or the like and covers the outer surface of the via 230, in order to prevent a short circuit with the semiconductor substrate 200. Furthermore, a barrier metal film (not illustrated) for preventing diffusion of metal atoms from the via 230 to the semiconductor substrate 200 may be provided between the via 230 and the insulating film. The barrier metal film can be formed of, for example, a material such as a titanium nitride film.

Further, the anode electrode 240 for electrically connecting the light emitting element 220 and the via 230 is provided on the surface (second surface) 200b of the semiconductor substrate 200 opposite to the surface (first surface) 200a. facing the semiconductor substrate 100, below the light emitting unit 20. For example, the anode electrode 240 can be formed of a metal film containing copper, tungsten, aluminum, tantalum, or the like, or a transparent conductive film such as indium tin oxide (ITO) or indium zinc oxide (IZO). Further, the organic material layer 274, the cathode electrode 272, the insulating film 270, and the color filters 222 are stacked on the anode electrode 240.

Note that, in the present embodiment, because of provision of the peripheral circuit transistor 300 having a low breakdown voltage on the semiconductor substrate 200, the film thickness of the semiconductor substrate 200 can be reduced. As a result, the aspect ratio of the via 230 passing through the semiconductor substrate 200 can be reduced. Thus, the aspect ratio can be reduced, and hence an embedding failure can be prevented from occurring during embedding of a metal film or the into a through hole in forming the via 230. Further, the length of the via 230 (the length along the stacking direction of the display apparatus 10) can also be shortened, and hence a delay in driving the light emitting element 220 can be prevented.

Moreover, in the present embodiment, the wire lengths between the light emitting elements 220 and the pixel transistors 400 of the same kind are preferably substantially the same so that signal voltages are uniformly applied to each light emitting element 220.

As described above, the semiconductor substrates 100 and 200 include the wiring layers 102 and 202, respectively, and the semiconductor substrate 100 and the semiconductor substrate 200 are bonded to each other by bonding of the wiring layers 102 and 202 to each other. For example, in the present embodiment, the semiconductor substrate 100 and the semiconductor substrate 200 may be bonded to each other by Cu—Cu bonding of the wires 104 that are formed of copper and provided in the wiring layer 102 and the wires 204 that are formed of copper and provided in the wiring layer 202. Alternatively, in the present embodiment, the semiconductor substrate 100 and the semiconductor substrate 200 may be bonded to each other by bonding of a via (not illustrated) provided in the wiring layer 102 and a via (not illustrated) provided in the wiring layer 202. Furthermore, in the present embodiment, the method of bonding the semiconductor substrates 100 and 200 is not limited to the above-described method. For example, a solid phase bonding method such as plasma bonding or diffusion bonding may be employed.

Further, in the present embodiment, bonding is not limited to the above-described bonding between the semiconductor substrates, and may be bonding between chips or bonding between a semiconductor substrate and a chip depending on ease of bonding, a yield, and the like.

As described above, in the present embodiment, the display apparatus 10 has a structure obtained by a process in which the peripheral circuit transistor 300 and the pixel transistor 400 having different characteristics and configurations are provided on the different semiconductor substrates 100 and 200, respectively, and the semiconductor substrates 100 and 200 are stacked and bonded. Therefore, in the present embodiment, the semiconductor substrates 100 and 200 including transistors having different characteristics and configurations can be efficiently manufactured by different processes suitable for the substrates, respectively. Further, in the present embodiment, the gate oxide film 404 of the pixel transistor 400 can be formed thick, which allows the pixel transistor 400 to suitably operate despite a high drive voltage applied to the light emitting element 220. Moreover, in the present embodiment, the peripheral circuit transistor 300 can be formed as a minute transistor with the thin gate oxide film 304. Thus, it is possible to prevent a delay from occurring while mitigating an increase of the area of the peripheral circuit unit 30 despite an increase of the number of the peripheral circuit transistors 300 for higher definition and higher resolution of the display apparatus 10.

In other words, according to the present embodiment, the display apparatus 10 can mitigate an increase of a mounting area and allow efficient manufacture while meeting a demand for higher definition and higher resolution.

Note that the present embodiment is not limited to a configuration in which all kinds of the pixel transistors (TR_{Drv}, TR_{Sig}, TR_{EL_C1}, TR_{EL_C2}) 400 are provided on the semiconductor substrate 100, and some kinds of the pixel transistors 400 may be provided on the semiconductor substrate 200. However, depending on the kind of the pixel transistor provided on the semiconductor substrate 200, it may be required to provide a via (not illustrated) passing through the semiconductor substrate 200 between the light emitting elements 220. In such a case, due to provision of the above-described via, the light emitting element 220 and an interval between the light emitting elements 220 are widened, which may possibly increase the area of the light emitting unit 20 or reduce the number of pixels. Then, in the present embodiment, it is preferable to select the kind of pixel transistor provided on the semiconductor substrate 200 so as to avoid such a situation.

<2.2 Modifications>

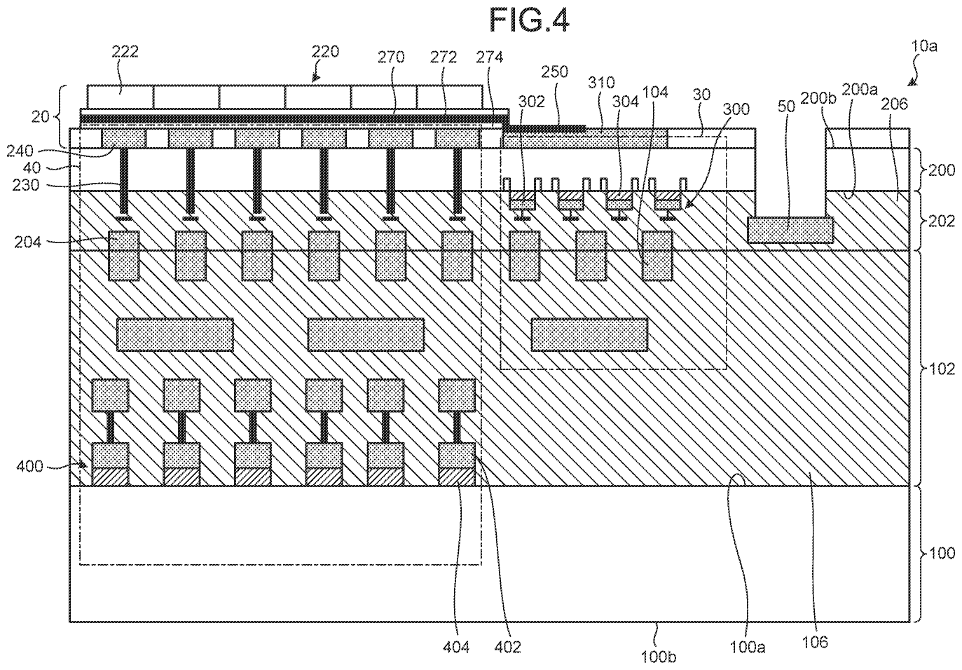

Next, a sectional structure of a display apparatus 10a according to a modification of the first embodiment of the present disclosure will be described with reference to FIG. 4. FIG. 4 is a sectional view diagrammatically illustrating an example of a sectional structure of the display apparatus 10a according to the present embodiment. In FIG. 4, the gate oxide films 304 and 404 are illustrated such that they are thicker than layers other than the gate oxide films 304 and 404 for the purpose of emphasizing that their film thicknesses differ depending on in which transistor they are included, in the present modification. Further, in FIG. 4, illustration of the organic material layer 274, the cathode electrode 272, and the insulating film 270 is omitted.

In the present modification, as illustrated in FIG. 4, a wire 250 formed of a conductive material such as a metal film, for example, and a contact (cathode contact) 310 electrically connected to the wire 250 are provided on the surface (second surface) 200b of the semiconductor substrate 200 opposite to the surface (first surface) 200a facing the semiconductor substrate 100, to electrically connect the cathode electrode 272 of the light emitting element 220 of the light emitting unit 20 to the power supply circuit. Specifically, as illustrated in FIG. 4, the contact 310 is positioned immediately above (directly above) the peripheral circuit unit 30. Note that, in the present modification, the contact 310 is not necessarily required to be positioned immediately above (directly above) the peripheral circuit unit 30, and may be positioned between the light emitting unit 20 and the peripheral circuit unit 30 in plan view of the semiconductor substrate 200. Further, in the present modification, the wiring layer 202 may be provided with a pad 50 for making connection to another substrate (not illustrated) or another unit.

<2.3 Manufacturing Method>

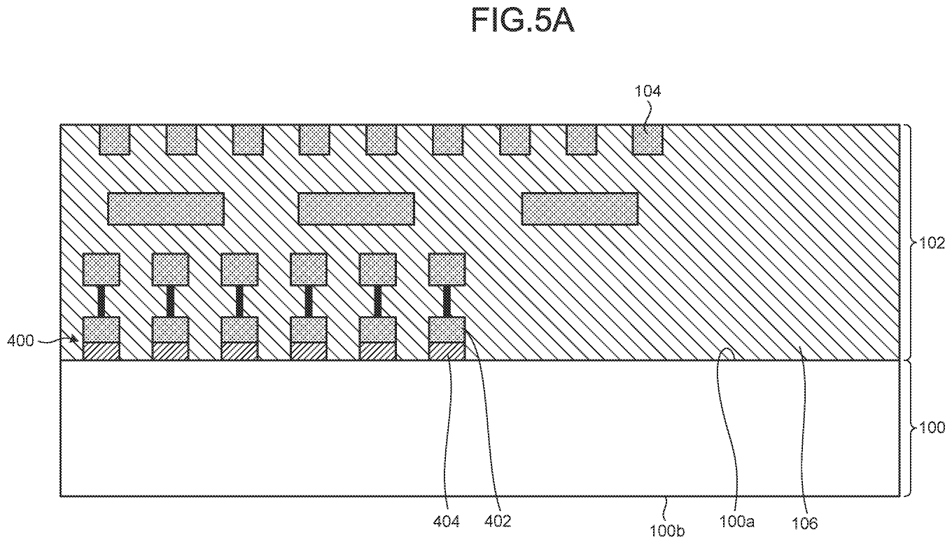

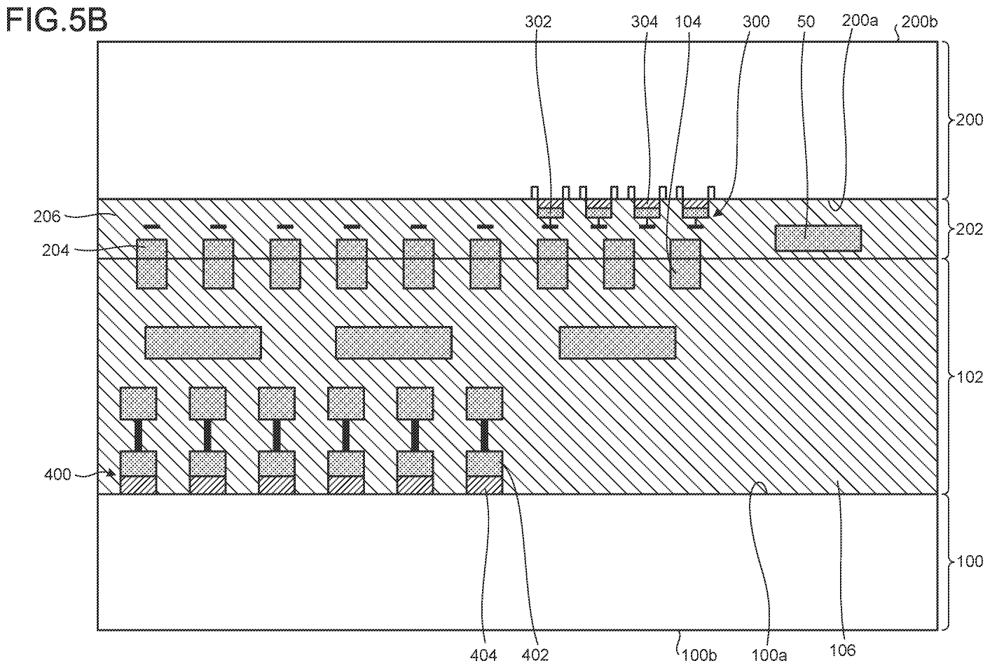

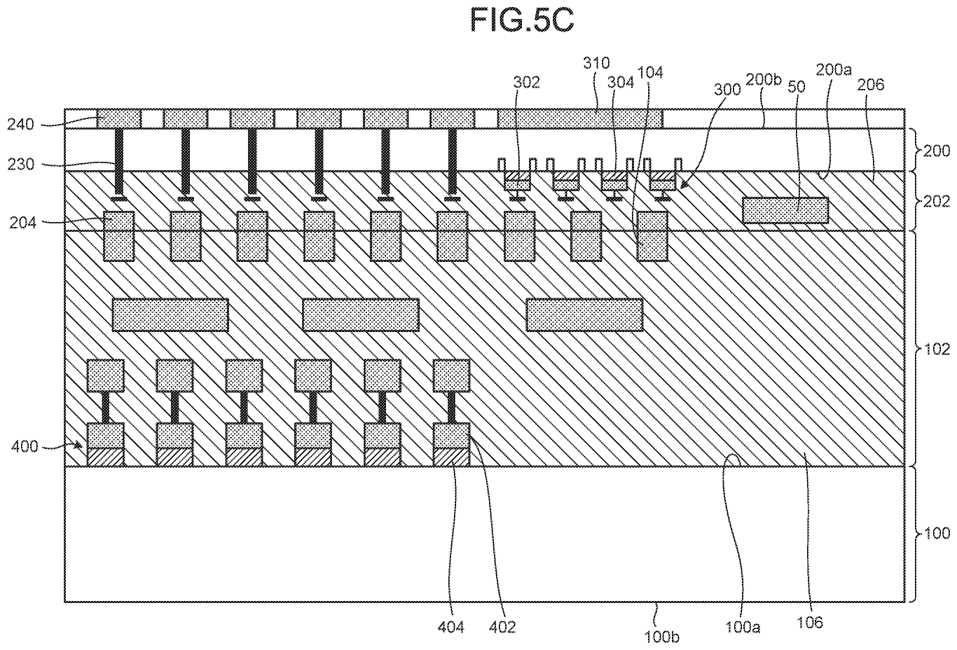

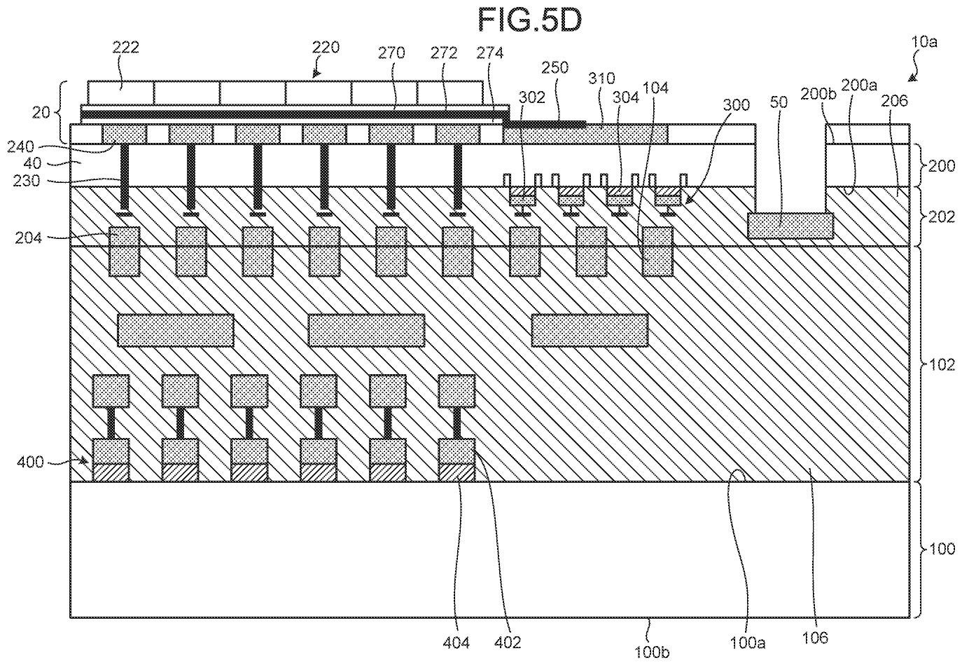

Next, a method of manufacturing the display apparatus 10a will be described with reference to FIGS. 5A to 5D. FIGS. 5A to 5D are explanatory views for explaining the method of manufacturing the display apparatus 10a according to the first embodiment of the present disclosure, and specifically, illustrate sections of the display apparatus 10a in respective stages of the manufacturing method, corresponding to the sectional view of the display apparatus 10a in FIG. 4. Note that, in FIGS. 5A to 5D, the gate oxide films 304 and 404 are illustrated such that they are thicker than layers other than the gate oxide films 304 and 404 for the purpose of emphasizing that their film thicknesses differ depending on in which transistor they are included, in the present embodiment. Further, in FIG. 5D, illustration of the organic material layer 274, the cathode electrode 272, and the insulating film 270 is omitted.

First, the drive circuit unit 40 (not illustrated in FIG. 5A) including a pixel transistor group including the plurality of pixel transistors 400 that drive the light emitting unit 20 and the wiring layer 102 are formed on the semiconductor substrate 100, thereby obtaining the semiconductor substrate 100 as illustrated in FIG. 5A. In the present embodiment, in forming the semiconductor substrate 100, the plurality of pixel transistors 400 are formed such that the film thickness of the gate oxide film 404 of each of the plurality of pixel transistors 400 is larger than the film thickness of the gate oxide film 304 of each of the plurality of peripheral circuit transistors 300 provided on the semiconductor substrate 200. Further, in the present embodiment, the wires 104 that are electrically connected to the semiconductor substrate 200 and can also be used for bonding are formed in the wiring layer 102.

Subsequently, the peripheral circuit unit 30 (not illustrated in FIG. 5B) including the plurality of peripheral circuit transistors 300 that supply a signal voltage to the drive circuit unit 40 (not illustrated in FIG. 5B) and the wiring layer 202 are formed on the semiconductor substrate 200, thereby obtaining the semiconductor substrate 200 as illustrated in FIG. 5B. In the present embodiment, in forming the semiconductor substrate 200, the plurality of peripheral circuit transistors 300 are formed such that the film thickness of the Gate oxide film 304 of each of the plurality of peripheral circuit transistors 300 is smaller than the film thickness of the gate oxide film 404 of each of the plurality of pixel transistors 400 provided on the semiconductor substrate 100. Further, in the present embodiment, the wires 204 that are electrically connected to the semiconductor substrate 100 and can also be used for bonding are formed the wiring layer 202.

Subsequently, the semiconductor substrate 200 is stacked on the semiconductor substrate 100 such that the wiring layers 102 and 202 face each other, and the semiconductor substrate 100 and the semiconductor substrate 200 are bonded by heating or the like. In this manner, as illustrated in FIG. 5B, the semiconductor substrate 100 and the semiconductor substrate 200 are integrated, and the peripheral circuit transistors 300 of the peripheral circuit unit 30 and the pixel transistors 400 of the drive circuit unit 40 are electrically connected via the wires 104 and 204.

Subsequently, the surface (second surface) 200b of the semiconductor substrate 200 opposite to the surface (first surface) 200a facing the semiconductor substrate 100 is polished, so that the semiconductor substrate 200 is thinned (thinning process). Further, the via 230, the anode electrode 240, and the contact 310 are formed in the semiconductor substrate 200, thereby obtaining a configuration as illustrated in FIG. 5C.

Further, the insulating film 270 provided with the wire 250 is formed on the surface (second surface) 200b of the semiconductor substrate 200 opposite to the surface (first surface) 200a facing the semiconductor substrate 100, and the plurality of light emitting elements 220 are formed on the insulating film 270, thereby obtaining the display apparatus 10a as illustrated in FIG. 5D.

Note that, in the present embodiment, also a surface 100b of the semiconductor substrate 100 may be subjected to a thinning process, as necessary.

In the present embodiment, examples of a method of forming each layer or each film described above include a physical vapor deposition (PVD) method, a chemical vapor deposition (CVD), and the like. Examples of the PVD method include a vacuum vapor deposition method using resistance heating or high frequency heating, an electron beam (EB) vapor deposition method, various sputtering methods (magnetron sputtering method, a radio frequency (RF)-direct current (DC) coupled bias sputtering method, an electron cyclotron resonance (ECR) sputtering method, a facing target sputtering method, a radio frequency sputtering method, and the like), an ion plating method, a laser ablation method, and a molecular beam epitaxy (MBE) method, a laser transfer method, and the like. Examples of the CVD method include a plasma CVD method, a thermal CVD method, an MOCVD method, an optical CVD method, and the like. Further, other methods include: an electrolytic plating method or an electroless plating method; a spin coating method; a dipping method; a casting method; a micro-contact printing method; a drop casting method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a casting coater method, a spray coater method, a slit orifice coater method, and a calendar coater method. Examples of a method of patterning each layer include chemical etching such as shadow masking, laser transfer, and photolithography, physical etching using ultraviolet rays, laser, or the like, and the like. In addition, examples of a planarization technique include a chemical mechanical polishing (CMP) method, a laser planarization method, a reflow method, and the like. That is, the display apparatus 10a according to the present embodiment can be easily and inexpensively manufactured using existing semiconductor-apparatus manufacturing processes.

As described above, in the present embodiment, the display apparatus 10a is obtained by a process in which the peripheral circuit transistor 300 and the pixel transistor 400 having different characteristics and configurations are provided on the different semiconductor substrates 100 and 200, respectively, and the semiconductor substrates 100 and 200 are stacked and bonded. Therefore, in the present embodiment, the semiconductor substrates 100 and 200 including transistors having different characteristics and configurations can be efficiently manufactured by different processes suitable for the substrates, respectively. Further, in the present embodiment, the gate oxide film 404 of the pixel transistor 400 can be formed thick, which allows the pixel transistor 400 to suitably operate despite a high drive voltage applied to the light emitting element 220. Moreover, in the present embodiment, the peripheral circuit transistor 300 can be formed as a minute transistor with the thin gate oxide film 304. Thus, it is possible to prevent a delay from occurring while mitigating an increase of the area of the peripheral circuit unit 30 despite an increase of the number of the peripheral circuit transistors 300 for higher definition and higher resolution of the display apparatus 10.

### 3. Second Embodiment

<3.1 Sectional Structure>

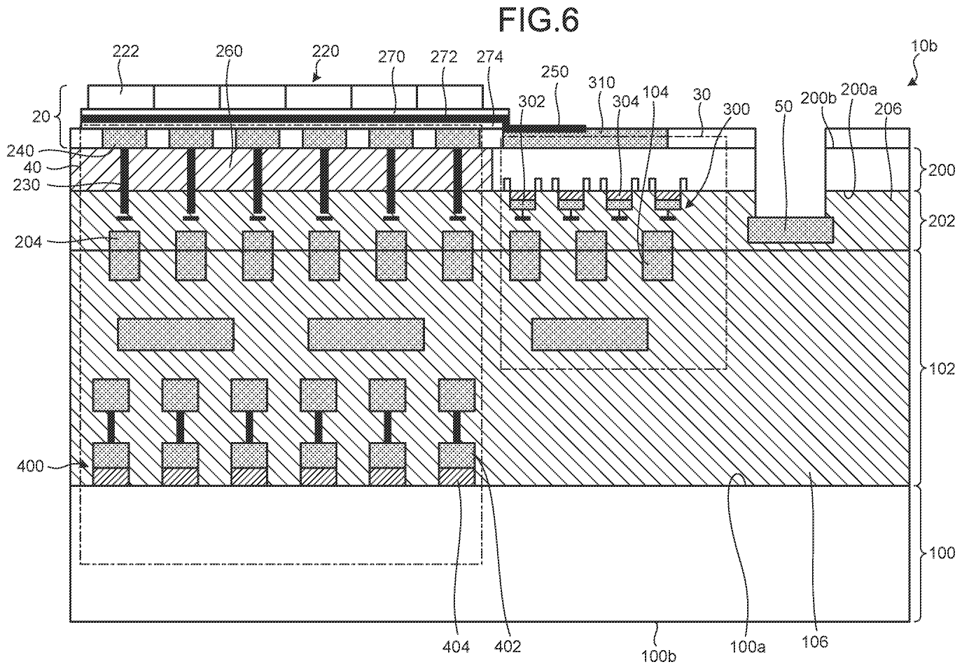

Next, a sectional structure of a display apparatus 10b according to a second embodiment of the present disclosure will be described with reference to FIG. 6. FIG. 6 is a sectional view diagrammatically illustrating an example of a sectional structure of the display apparatus 10b according to the present embodiment. In FIG. 6, the gate oxide films 304 and 404 are illustrated such that they are thicker than layers other than the gate oxide films 304 and 404 for the purpose of emphasizing that their film thicknesses differ depending on in which transistor they are included, in each embodiment. Further, in FIG. 6, illustration of the organic material layer 274, the cathode electrode 272, and the insulating film 270 is omitted.

In the first embodiment described above, the via 230 electrically connecting the light emitting element 220 and the drive circuit unit 40 is formed so as to pass through the semiconductor substrate 200. However, in the present embodiment, the via is formed so as to pass through not the semiconductor substrate 200, but an insulating film 260. With this configuration, it is possible to avoid providing an insulating film for preventing a short circuit with the semiconductor substrate 200 in the via 230. Further, since the insulating film 260 can be easily formed thin, the aspect ratio of the via 230 can be reduced. Thus, the aspect ratio can be reduced, and hence an embedding failure can be prevented from occurring during embedding of a metal film or the like into a through hole in forming the via 230. Moreover, the length of the via 230 (the length along the stacking direction of the display apparatus 10b) can also be shortened, and hence a delay in driving the light emitting element 220 can be prevented.

Specifically, in the present embodiment, as illustrated in FIG. 6, the insulating film 260 is provided on the wiring layer 202 and below the light emitting unit 20. Then, the via 230 electrically connecting the light emitting element 220 and the drive circuit unit 40 is formed so as to pass through the insulating film 260.

<3.2 Manufacturing Method>

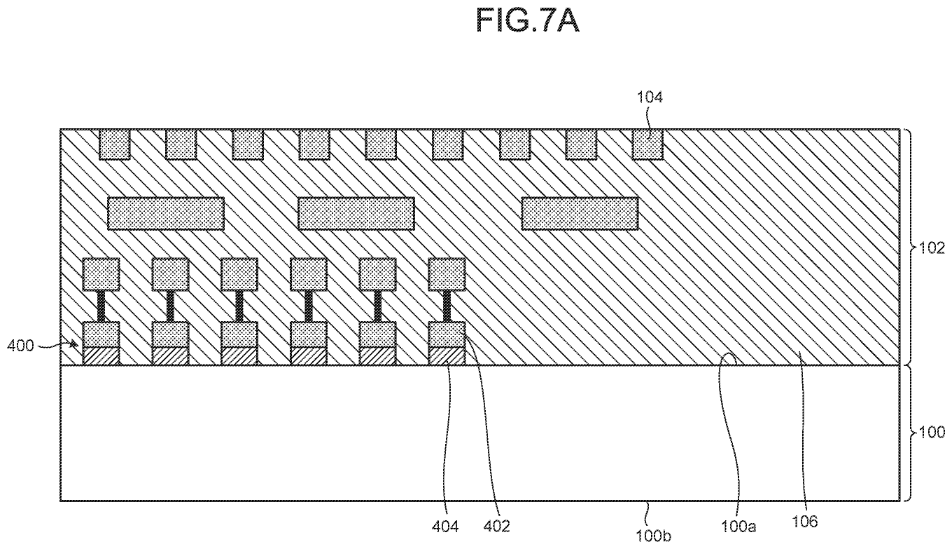

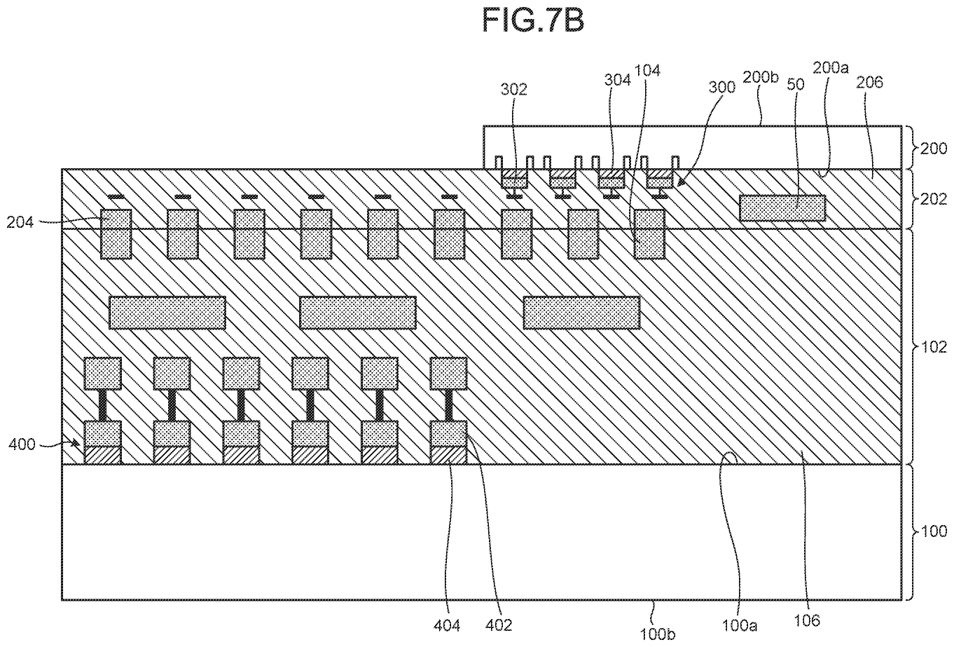

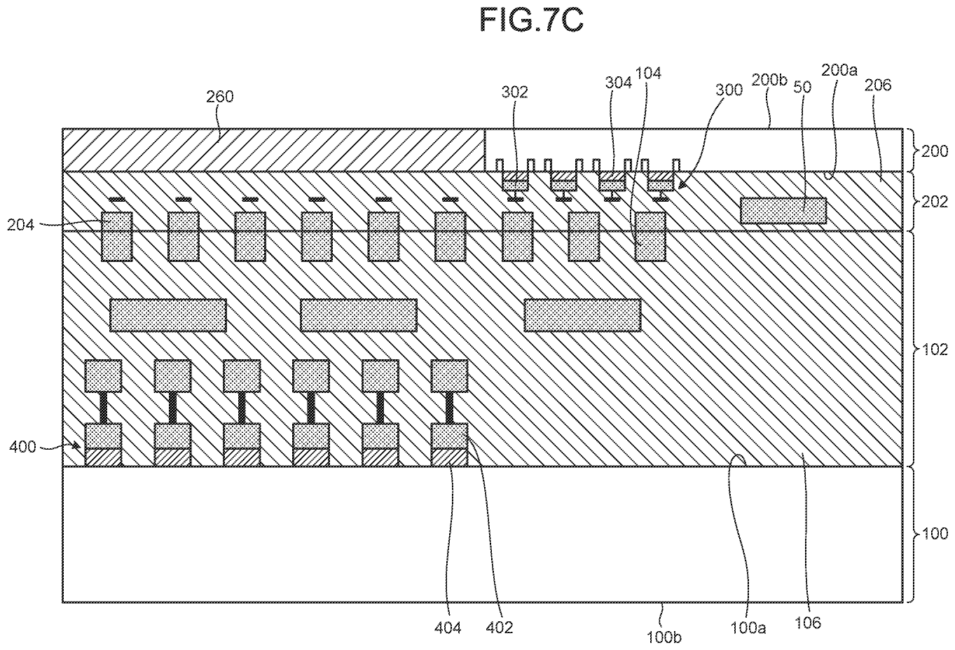

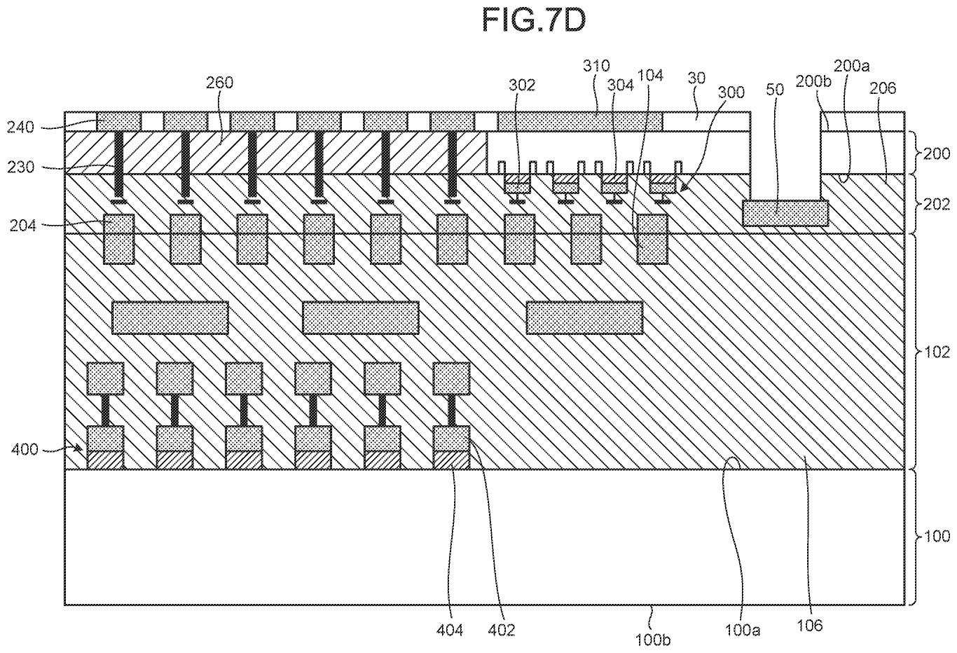

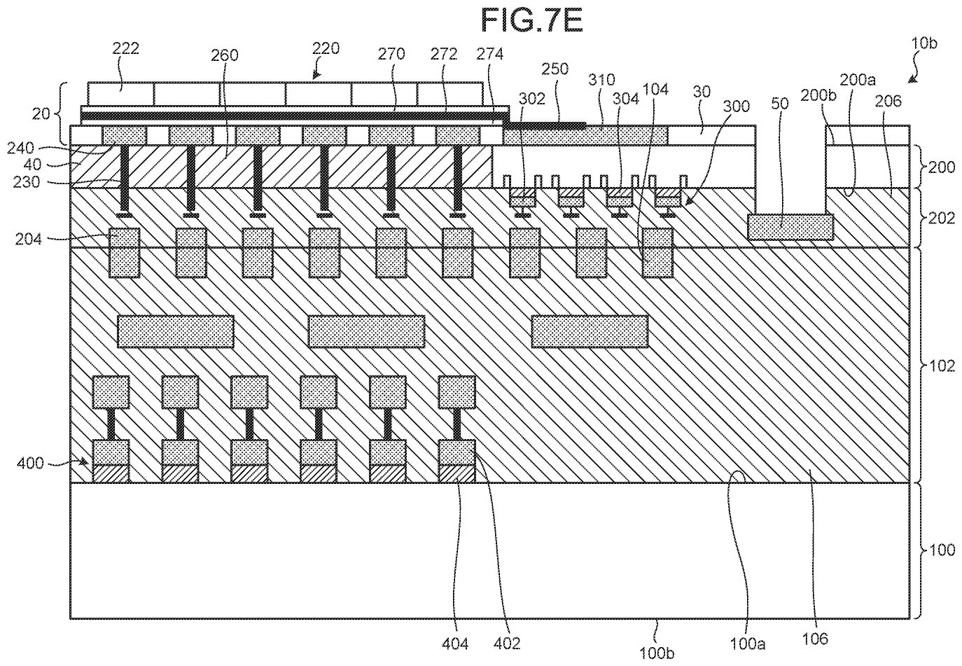

Next, a method of manufacturing the display apparatus 10b according to the present embodiment will be described with reference to FIGS. 7A to 7E. FIGS. 7A to 7E are explanatory views for explaining the method of manufacturing the display apparatus 10b according to the second embodiment of the present disclosure, and specifically, illustrate sections of the display apparatus 10b in respective stages of the manufacturing method, corresponding to the sectional view of the display apparatus 10b in FIG. 6. Note that, in FIGS. 7A to 7E, the gate oxide films 304 and 404 are illustrated such that they are thicker than layers other than the gate oxide films 304 and 404 for the purpose of emphasizing that their film thicknesses differ depending on in which transistor they are included, in the present embodiment. Further, in FIG. 7E, illustration of the organic material layer 274, the cathode electrode 272, and the insulating film 270 is omitted.

First, the drive circuit unit 40 (not illustrated in FIG. 7A) including a pixel transistor group including the plurality of pixel transistors 400 that drive the light emitting unit 20 and the wiring layer 102 are formed on the semiconductor substrate 100, thereby obtaining the semiconductor substrate 100 as illustrated in FIG. 7A. Note that the details of the manufacturing method are similar to those of the manufacturing method according to the first embodiment described with reference to FIG. 5A, and thus detailed description is omitted here.

Subsequently, the peripheral circuit unit 30 (not illustrated in FIG. 7B) including the plurality of peripheral circuit transistors 300 that supply a signal voltage or the like to the drive circuit unit 40 (not illustrated in FIG. 7B) and the wiring layer 202 are formed on the semiconductor substrate 200, thereby obtaining the semiconductor substrate 200 as illustrated in FIG. 7B. Then, the semiconductor substrate 200 is stacked on the semiconductor substrate 100 such that the wiring layers 102 and 202 face each other, and the semiconductor substrate 100 and the semiconductor substrate 200 are bonded by heating or the like. In this manner, the semiconductor substrate 100 and the semiconductor substrate 200 are integrated, and the peripheral circuit transistors 300 of the peripheral circuit unit 30 and the pixel transistors 400 of the drive circuit unit 40 are electrically connected via the wires 104 and 204. Furthermore, a part of the semiconductor substrate 200 on a side closer to the drive circuit unit 40, in other words, a part that should be eventually positioned below the light emitting unit 20, is removed, and the surface 200b of the remaining part of the semiconductor substrate 200 is subjected to a thinning process, thereby obtaining a configuration as illustrated in FIG. 7B.

Subsequently, the insulating film 260 is formed in the region where the semiconductor substrate 200 has been removed, thereby obtaining a configuration as illustrated in FIG. 7C.

Further, the via 230, the anode electrode 240, and the contact 310 are formed in the semiconductor substrate 200 and the insulating 260, thereby obtaining a configuration as illustrated in FIG. 7D.

Further, the insulating film 270 provided with the wire 250 is formed on the surface (second surface) 200b of the semiconductor substrate 200 opposite to the surface (first surface) 200a facing the semiconductor substrate 100, and the plurality of light emitting elements 220 are formed on the insulating film 270, thereby obtaining the display apparatus 10b as illustrated in FIG. 7E.

### 4. Third Embodiment

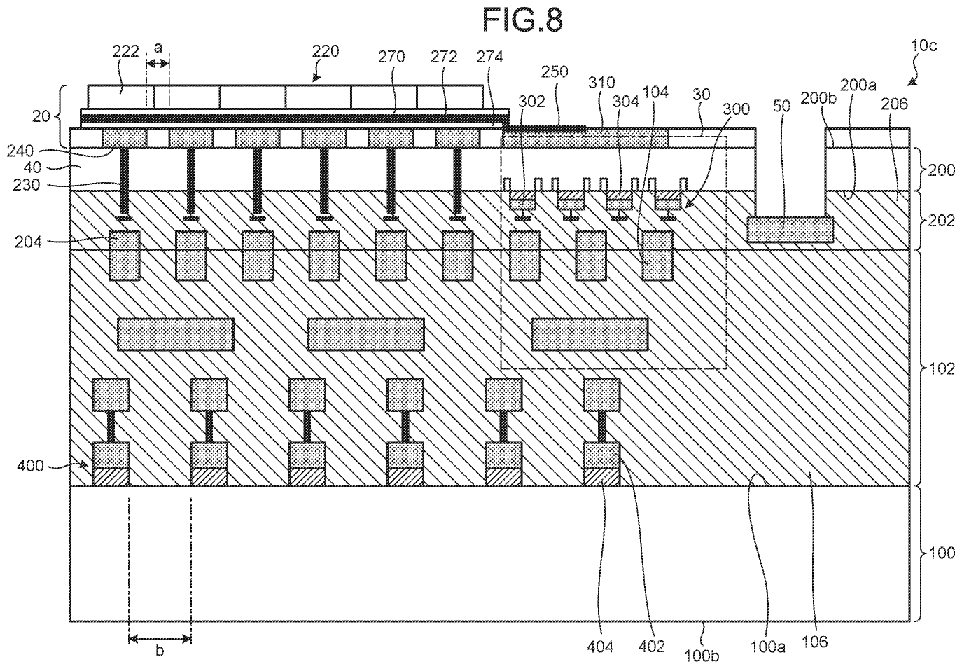

Next, a sectional structure of a display apparatus 10c according to a third embodiment of the present disclosure will be described with reference to 8. FIG. 8 is a sectional view diagrammatically illustrating an example of a sectional structure of the display apparatus 10c according to the present embodiment. In FIG. 8, the gate oxide films 304 and 404 are illustrated such that they are thicker than layers other than the gate oxide films 304 and 404 for the purpose of emphasizing that their film thicknesses differ depending on in which transistor they are included, in the present embodiment. Further, in FIG. 8, illustration of the organic material layer 274, the cathode electrode 272, and the insulating film 270 is omitted.

In the present embodiment, as illustrated in FIG. 8, the peripheral circuit unit 30 is positioned above the pixel transistors 400 of the drive circuit unit 40. Further, an interval b between the pixel transistors 400 according to the present embodiment is made wider than an interval (pitch) between the pixel transistors 400 according to the first embodiment described above. Further, in the present embodiment, an interval between adjacent ones of the plurality of light emitting elements 220 (specifically, an interval a between adjacent ones of the plurality of anode electrodes 240) is narrower than the interval b between adjacent ones of the plurality of pixel transistors 400. With this configuration, according to the present embodiment, the interval (pitch) b between the pixel transistors 400 can be increased with the interval (pitch) a between the anode electrodes 240 that affects the resolution of the display apparatus 10c being kept small, whereby the breakdown voltage of the pixel transistors 400 can be kept higher.

Note: that, also in the present embodiment, preferably, routing of the wires is so designed that the wire lengths between the light emitting elements 220 and the pixel transistors 400 of the same kind are substantially the same so that signal voltages are uniformly applied to each light emitting element 220.

### 5. Conclusion

As described above, according to each of the embodiments of the present disclosure, the display apparatus 10 that can mitigate an increase of a mounting area and allow efficient manufacture while meeting a demand for higher definition and higher resolution, can be provided.

More specifically, in each of the embodiments of the present disclosure, the display apparatus 10 has a structure obtained by a process in which the peripheral circuit transistor 300 and the pixel transistor 400 having different characteristics and configurations are provided on the different semiconductor substrates 100 and 200, respectively, and the semiconductor substrates 100 and 200 are stacked and bonded. Therefore, in the present embodiment, the semiconductor substrates 100 and 200 including transistors having different characteristics and configurations can be efficiently manufactured by different processes suitable for the substrates, respectively. Further, in the present embodiment, the gate oxide film 404 of the pixel transistor 400 can be formed thick, which allows the pixel transistor 400 to suitably operate despite a high drive voltage applied to the light emitting element 220. Moreover, in the present embodiment, the peripheral circuit transistor 300 can be formed as a minute transistor with the thin gate oxide film 304. Thus, it is possible to prevent a delay from occurring while mitigating an increase of the area of the peripheral circuit unit 30 despite an increase of the number of the peripheral circuit transistors 300 for higher definition and higher resolution of the display apparatus 10.

Furthermore, in the above-described embodiments of the present disclosure, the semiconductor substrates 100 and 200 are not necessarily required to be silicon substrates, and may be other substrates (for example, a silicon-on-insulator (SOT) substrate, a SiGe substrate, or the like).

Furthermore, in the drawings referred to in the above-described embodiments of the present disclosure, various insulating films and the like are illustrated in a simplified manner for easier understanding in some cases. However, in practice, these insulating films and the like may be layered films made of a plurality of different insulating materials, or may be layered films formed by a plurality of different processes.

### 6. Application Examples

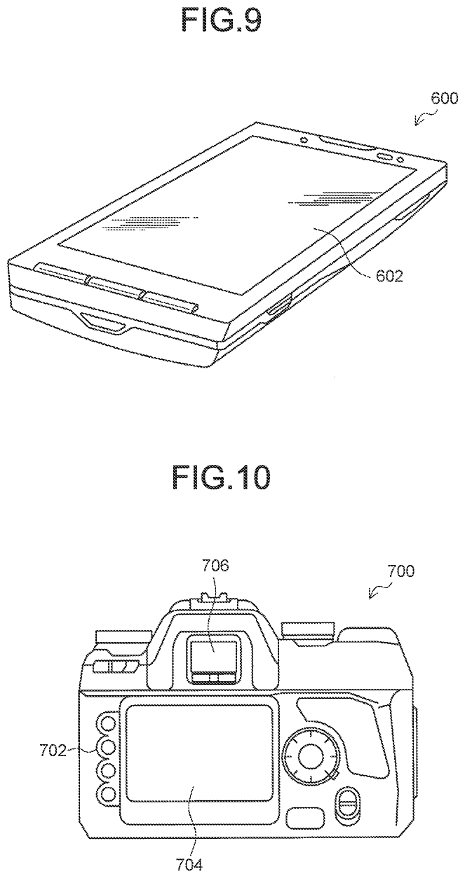

Next, application examples of the display apparatus 10 according to the embodiments of the present disclosure will be described with reference to FIGS. 9 to 12. FIGS. 9 to 12 are external views illustrating examples of an electronic apparatus to which the display apparatus 10 according to the embodiments of the present disclosure can be applied.

For example, the display apparatus 10 according to the present embodiments can be applied to a display unit included in an electronic apparatus such as a smartphone. Specifically, as illustrated in FIG. 9, a smartphone 600 includes a display unit 602 that displays various kinds of information, an operation unit including a button or the like that receives an input of a user's operation, and the like. The above-described display unit 602 can be the display apparatus 10 according to the present embodiments.

Alternatively, for example, the display apparatus 10 according to the present embodiments can be applied to a display unit of an electronic apparatus such as a digital camera. Specifically, as illustrated in an external view of FIG. 10 that shows a digital camera 700 as viewed from the rear (photographer side), the digital camera 700 includes a main unit (camera body) 702, a monitor 704 that displays various kinds of information, and an electronic view finder (EVF) 706 that displays a through image observed by a user at the time of photographing. The monitor 704 and the EVF 706 can be the display apparatus 10 according to the present embodiments.

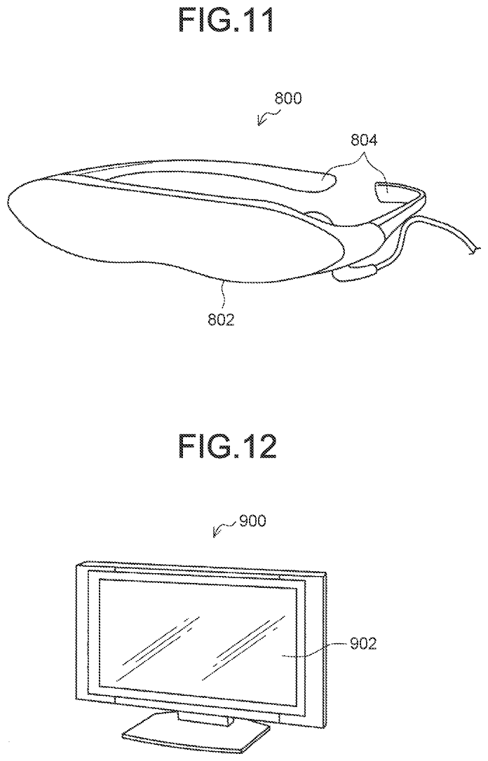

Alternatively, for example, the display apparatus 10 according to the present embodiments can be applied to a display unit of an electronic apparatus such as a head mounted display (HMD). Specifically, as illustrated in FIG. 11, a HMD 800 includes an eyeglass type display unit 802 that displays various kinds of information, and an ear hook 804 that is hooked onto a user's ears when worn. The display unit 802 can be the display apparatus 10 according to the present embodiments.

Alternatively, for example, the display apparatus 10 according to the present embodiments can be applied to a display unit of an electronic apparatus such as a television apparatus or the like. Specifically, as illustrated in FIG. 12, a television apparatus 900 includes a display unit 902 covered with filter glass or the like. The display unit 902 can be the display apparatus 10 according to the present embodiments.

Note that an electronic apparatus to which the display apparatus 10 according to the present embodiments can be applied is not limited to the above-described examples. The display apparatus 10 according to the present embodiments can be applied to a display unit of an electronic apparatus in any field that performs display based on an externally-input image signal or an internally-generated image signal. Examples of such an electronic apparatus include a television apparatus, an electronic book, a personal digital assistant (PDA), a notebook personal computer, a video camera, a smart watch, a game console, and the like.

### 7. Supplement

While the preferred embodiments of the present disclosure have been described above in detail with reference to the accompanying drawings, the technical scope of the present disclosure is not limited to those embodiments. It is obvious that a person having ordinary knowledge in the technical field of the present disclosure can conceive various changes or modifications within the scope of the technical idea described in the claims, and it is naturally understood that these also fall within the technical scope of the present disclosure.

Further, the effects described in the present specification are merely illustrative or exemplary, and are not restrictive. That is, the techniques according to the present disclosure can produce other effects obvious to those skilled in the art from the description of the present specification, in addition to, or in place of, the above-described effects.

Moreover, the present techniques can also have the following configurations.
(1) A display apparatus comprising:
   a first semiconductor substrate provided with a drive circuit unit including a pixel transistor group including a plurality of pixel transistors that drives a light emitting unit; and
   a second semiconductor substrate provided with the light emitting unit and a peripheral circuit unit including a plurality of peripheral circuit transistors that supplies a signal voltage to the drive circuit unit, the second semiconductor substrate being stacked on the first semiconductor substrate and bonded to the first semiconductor substrate, wherein
   a film thickness of a gate oxide film of each of the plurality of pixel transistors is larger than a film thickness of a gate oxide film of each of the plurality of peripheral circuit transistors.
(2) The display apparatus according to (1), wherein the peripheral circuit unit is positioned around the light emitting unit in plan view of the display apparatus.
(3) The display apparatus according to (1) or (2), wherein the light emitting unit is positioned immediately above the drive circuit unit along a stacking direction of the display apparatus.
(4) The display apparatus according to (3), wherein the light emitting unit and the drive circuit unit are electrically connected via a via passing through the second semiconductor substrate.
(5) The display apparatus according to (3), wherein the light emitting unit and the drive circuit unit are electrically connected via a via passing through an insulating film.
(6) The display apparatus according to (3), wherein
   the peripheral circuit unit is provided on a side closer to first surface of the second semiconductor substrate facing the first semiconductor substrate, and
   the light emitting unit is provided on a side closer to a second surface of the second semiconductor substrate opposite to the first surface.
(7) The display apparatus according to (6), wherein the light emitting unit includes plurality of light emitting elements arranged along a row direction and a column direction.
(8) The display apparatus according to (7), wherein the pixel transistor group is provided so as to correspond to each of the plurality of light emitting elements.
(9) The display apparatus according to (7) or (8), wherein a contact electrically connecting electrodes of the plurality of light emitting elements to a power supply circuit is provided on the side closer to the second surface of the second semiconductor substrate.
(10) The display apparatus according to (9), wherein the contact is positioned immediately above the peripheral circuit unit along the stacking direction.
(11) The display apparatus according to any one of (7) to (10), wherein the peripheral circuit unit is positioned immediately above the drive circuit unit along the stacking direction.
(12) The display apparatus according to (11), wherein an interval between adjacent ones of the plurality of light emitting elements is narrower than an interval between adjacent ones of the plurality of pixel transistors.
(13) The display apparatus according to (12.), wherein wire lengths of wires electrically connecting each of the light emitting elements and each of the pixel transistors are substantially the same.
(14) The display apparatus according to any one of (7) to (13), wherein
   each of the first and second semiconductor substrates includes a wiring layer, and
   the wiring layers are bonded to each other, so that the first semiconductor substrate and the second substrate are bonded.
(15) The display apparatus according to any one of (7) to (14), wherein the pixel transistor group includes at least one of a transistor that drives the light emitting elements, a row selection transistor that operates in accordance with a row selection signal, a column selection transistor that operates in accordance with a column selection signal, and a reset transistor that resets a voltage applied to the light emitting elements.
(16) A method of manufacturing a display apparatus comprising:
   forming a first semiconductor substrate provided with a drive circuit unit including a pixel transistor group including a plurality of pixel transistors that drives a light emitting unit;
   forming a second semiconductor substrate provided with the light emitting unit and a peripheral circuit unit including a plurality of peripheral circuit transistors that supplies a signal voltage to the drive circuit unit; and
   stacking the second semiconductor substrate on the first semiconductor substrate to bond the substrates, wherein
   in forming the first semiconductor substrate, the plurality of pixel transistors are formed such that a film thickness of a gate oxide film of each of the plurality of pixel transistors is larger than a film thickness of a gate oxide film of each of the plurality of peripheral circuit transistors.
(17) An electronic apparatus in which one or a plurality of display apparatuses is mounted, wherein
   the display apparatuses each include:
   a first semiconductor substrate provided with a drive circuit unit including a pixel transistor group including a plurality of pixel transistors that drives a light emitting unit; and
   a second semiconductor substrate provided with the light emitting unit and a peripheral circuit unit including a plurality of peripheral circuit transistors that supplies a signal voltage to the drive circuit unit, the second semiconductor substrate being stacked on the first semiconductor substrate and bonded to the first semiconductor substrate, and
   a film thickness of a gate oxide film of each of the plurality of pixel transistors is larger than a film thickness of a gate oxide film of each of the plurality of peripheral circuit transistors.

### REFERENCE SIGNS LIST

10, 10a, 10b, 10c DISPLAY APPARATUS
20 LIGHT EMITTING UNIT
30 PERIPHERAL CIRCUIT UNIT
33 SCANNING CIRCUIT
34 LIGHT-EMISSION-CONTROL-TRANSISTOR CONTROL CIRCUIT
35 IMAGE-SIGNAL OUTPUT CIRCUIT
36 FIRST CURRENT SUPPLY UNIT
37 SECOND CURRENT SUPPLY UNIT
40 DRIVE CIRCUIT UNIT
50 PAD
100, 200 SEMICONDUCTOR SUBSTRATE
100a, 100b, 200a, 200b SURFACE
102, 202 WIRING LAYER
104, 204, 250 WIRE
106, 206, 260, 270 INSULATING FILM
220 LIGHT EMITTING ELEMENT
222 COLOR FILTER
230 VIA
240 ANODE ELECTRODE
272 CATHODE ELECTRODE
274 ORGANIC MATERIAL LAYER
300 PERIPHERAL CIRCUIT TRANSISTOR
302, 402 GATE ELECTRODE
304, 404 GATE OXIDE FILM
310 CONTACT
400 PIXEL TRANSISTOR
600 SMARTPHONE
602, 802, 902 DISPLAY UNIT
700 DIGITAL CAMERA
702 HAIN UNIT
704 MONITOR
706 EVF
800 HMD
804 EAR HOOK
900 TELEVISION APPARATUS

1. A display apparatus comprising:
a first semiconductor substrate provided with a drive circuit unit including a pixel transistor group including a plurality of pixel transistors that drives a light emitting unit; and
a second semiconductor substrate provided with the light emitting unit and a peripheral circuit unit including a plurality of peripheral circuit transistors that supplies a signal voltage to the drive circuit unit, the second semiconductor substrate being stacked on the first semiconductor substrate and bonded to the first semiconductor substrate, wherein
a film thickness of a gate oxide film of each of the plurality of pixel transistors is larger than a film thickness of a gate oxide film of each of the plurality of peripheral circuit transistors.

2. The display apparatus according to claim 1, wherein the peripheral circuit unit is positioned around the light emitting unit in plan view of the display apparatus.

3. The display apparatus according to claim 1, wherein the light emitting unit is positioned immediately above the drive circuit unit along a stacking direction of the display apparatus.

4. The display apparatus according to claim 3, wherein the light emitting unit and the drive circuit unit are electrically connected via a via passing through the second semiconductor substrate.

5. The display apparatus according to claim 3, wherein the light emitting unit and the drive circuit unit are electrically connected via a via passing through an insulating film.

6. The display apparatus according to claim 3, wherein
the peripheral circuit unit is provided on a side closer to a first surface of the second semiconductor substrate facing the first semiconductor substrate, and
the light emitting unit is provided on a side closer to a second surface of the second semiconductor substrate opposite to the first surface.

7. The display apparatus according to claim 6, wherein the light emitting unit includes a plurality of light emitting elements arranged along a row direction and a column direction.

8. The display apparatus according to claim 7, wherein the pixel transistor group is provided so as to correspond to each of the plurality of light emitting elements.

9. The display apparatus according to claim 7, wherein a contact electrically connecting electrodes of the plurality of light emitting elements to a power supply circuit is provided on the side closer to the second surface of the second semiconductor substrate.

10. The display apparatus according to claim 9, wherein the contact is positioned immediately above the peripheral circuit unit along the stacking direction.

11. The display apparatus according to claim 7, wherein the peripheral circuit unit is positioned immediately above the drive circuit unit along the stacking direction.

12. The display apparatus according to claim 11, wherein an interval between adjacent ones of the plurality of light emitting elements is narrower than an interval between adjacent ones of the plurality of pixel transistors.

13. The display apparatus according to claim 12, wherein wire lengths of wires electrically connecting each of the light emitting elements and each of the pixel transistors are substantially the same.

14. The display apparatus according to claim 7, wherein
each of the first and second semiconductor substrates includes a wiring layer, and
the wiring layers are bonded to each other, so that the first semiconductor substrate and the second substrate are bonded.

15. The display apparatus according to claim 7, wherein the pixel transistor group includes at least one of a transistor that drives the light emitting elements, a row selection transistor that operates in accordance with a row selection signal, a column selection transistor that operates in accordance with a column selection signal, and a reset transistor that resets a voltage applied to the light emitting elements.

16. A method of manufacturing a display apparatus comprising:
forming a first semiconductor substrate provided with a drive circuit unit including a pixel transistor group including a plurality of pixel transistors that drives a emitting unit;
forming a second semiconductor substrate provided with the light emitting unit and a peripheral circuit unit including a plurality of peripheral circuit transistors that supplies a signal voltage to the drive circuit unit; and
stacking the second semiconductor substrate on the first semiconductor substrate to bond the substrates, wherein
in forming the first semiconductor substrate, the plurality of pixel transistors are formed such that a film thickness of a gate oxide film of each of the plurality of pixel transistors is larger than a film thickness of a gate oxide film of each of the plurality of peripheral circuit transistors.

17. An electronic apparatus in which one or a plurality of display apparatuses is mounted, wherein
the display apparatuses each include:
a first semiconductor substrate provided with a drive circuit unit including a pixel transistor group including a plurality of pixel transistors that drives a light emitting unit; and
a second semiconductor substrate provided with the light emitting unit and a peripheral circuit unit including a plurality of peripheral circuit transistors that supplies a signal voltage to the drive circuit unit, the second semiconductor substrate being stacked on the first semiconductor substrate and bonded to the first semiconductor substrate, and
a film thickness of a gate oxide film of each of the plurality of pixel transistors is larger than a film thickness of a gate oxide film of each of the plurality of peripheral circuit transistors.
